(19) United States
(12) Patent Application Publication
(10) Pub. No.: US 2008/0299685 A1
(43) Pub. Date: Dec. 4, 2008

(54) One piece method for integrated circuit (IC) assembly

(75) Inventor: Akira Matsunami, Beppu City (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/807,581

(22) Filed: May 29, 2007

(51) Int. Cl. H01L 21/66; H01L 21/00

(52) U.S. Cl. 438/15; 29/25.01; 257/E21.521

(57) ABSTRACT

In a method and system for assembling a semiconductor device, a tray is configured to provide an array of bins arranged in m rows and n columns, where m and n are integers. The tray containing defect free singulated substrates is received from a substrate supplier for assembly. Each one of the defect free singulated substrates, which is disposed in a corresponding bin of the tray, is accessible in a concurrent or sequential manner, thereby enabling concurrent or sequential assembly of m*n ones of the defect free singulated substrate. The assembly process for the semiconductor device starting from the defect free singulated substrate includes die attach, wire bonding, mold press, laser marking, solder ball attach, and testing operations. Assembly of the defect free singulated substrates avoids material loss and increases manufacturing efficiency.

### BACKGROUND

The present disclosure relates generally to an assembly of a semiconductor device, and more particularly to a system and method for assembling a semiconductor device having components acquired from multiple sources.

Manufacturers of electrical/electronic devices such as integrated circuits (ICs), including system-on-a-chip (SoC), radio frequency (RF) circuit devices, printed circuit boards, and other electronic circuits, typically acquire materials and components used to manufacture, assemble, and package a semiconductor device from multiple suppliers. For example, a manufacturer of the semiconductor device may acquire substrate sheets from a substrate supplier, wafers containing several integrated circuit (IC) chips or dies from an IC fab (may be an in-house supplier), molding compound from a material supplier, and remaining components from other suppliers to assemble the semiconductor device.

It is well known that substrate suppliers typically provide substrates in the form of substrate sheets. Each one of the substrate sheets is generally in the form of a film strip-like sheet in which a plurality of substrates are formed consecutively to facilitate efficient handling in a subsequent process of manufacturing semiconductor devices. The strip-like substrate sheets are generally tested and marked, e.g., by an X mark, to identify particular substrates having a defect. The marked substrate sheets are supplied to a manufacturer of semiconductor devices for further assembly. The manufacturer may continue with the sequential processing of the strip-like substrate sheets, including defective ones, by performing assembly operations such as die attach, wire bonding, mold press, ball attach, and device marking. Thus, traditional assembly processing of a substrate sheet having a 10% defect ratio, e.g., ratio of defective substrates to the total number of substrates, may increase the material costs for the manufacturer by 10% and may reduce manufacturing efficiency by 10%. Therefore, a need exists to provide a method and system for efficiently assembling a semiconductor device.

### SUMMARY

Traditional assembly methods perform singulation of substrates after performing value added substrate operations such as die attach, wire bonding, molding, and marking. Applicant recognizes that performing value added assembly operations on potentially defective substrates may increase the material cost, increases waste, increases time, and reduces efficiency. The material costs may increase further if costly dies are used in the die attach process on defective substrates. It would be desirable to receive only defect free components, e.g., defect free singulated substrates, as a starting point in the assembly process and perform value added operations, e.g., die attach, wire bonding, molding, and similar others, on the defect free components.

Applicant recognizes a need to have improved tools and techniques for: 1) receiving singulated substrates that have been identified as being in compliance with acceptable quality standards (referred to as ‘defect free’), 2) receiving the singulated substrates that are arranged in a layout that a) enables the shipment of the defect free product, and b) permits sequential or parallel processing of the defect free singulated substrates, and 3) using assembly tools and techniques that are capable of performing operations in sequence or in parallel to fabricate the semiconductor device. Accordingly, it would be desirable to provide an improved method and system for assembling a semiconductor device, absent the disadvantages found in the prior methods discussed above.

The foregoing needs are addressed by the teachings of the present disclosure, which relates to a system and method for assembling a semiconductor device. According to one embodiment, in a method and system for assembling a semiconductor device, a tray is configured to provide an array of bins arranged in m rows and n columns, where m and n are integers. The tray containing defect free singulated substrates is received from a substrate supplier for assembly. Each one of the defect free singulated substrates, which is disposed in a corresponding bin of the tray, is accessible in a concurrent or sequential manner, thereby enabling concurrent or sequential assembly of m*n ones of the defect free singulated substrate. The assembly process for the semiconductor device starting from the defect free singulated substrate includes die attach, wire bonding, mold press, laser marking, solder ball attach, and testing operations. Assembly of the defect free singulated substrates avoids material loss and increases manufacturing efficiency.

Several advantages are achieved by the method and system according to the illustrative embodiments presented herein. The embodiments advantageously provide a method and system for assembling semiconductor devices by receiving defect free components for the assembly. By using defect free components as a starting point for the assembly, there are assured savings in material costs since no material is wasted on assembling defective semiconductor devices. The defect free singulated substrates used as the base for the semiconductor device assembly are advantageously identified as being in full compliance with acceptable quality standards (referred to as ‘defect free’). Each defect free singulated substrate is disposed in a corresponding bin of a tray, the bins being arranged in a matrix layout that advantageously provide access to tools for performing value added sequential or parallel processing operations on the defect free singulated substrate. Assembly operations including die attach, wire bonding, mold press, laser marking, solder ball attach, and testing may be advantageously performed in sequence or in parallel to efficiently fabricate the semiconductor device.

### BRIEF DESCRIPTION OF THE DRAWINGS

FIG. 1 illustrates a block diagram to fabricate defect free singulated substrates, according to an embodiment;

FIG. 2A illustrates a block diagram of a one piece assembly process for defect free singulated substrates described with reference to FIG. 1, according to an embodiment;

FIG. 2B is a block diagram illustrating additional detail of a die attach process described with reference to FIG. 2A, according to an embodiment;

FIG. 2C is a block diagram illustrating additional detail of a wire bonding process described with reference to FIG. 2A, according to an embodiment;

FIG. 2B illustrates a layout of a test marker used for alignment of a RTC described with reference to FIGS. 1A and 2A, according to an embodiment;

FIG. 2D is a block diagram illustrating additional detail of a mold press process described with reference to FIG. 2A, according to an embodiment;

FIG. 2E is a block diagram illustrating additional detail of a device marking process described with reference to FIG. 2A, according to an embodiment;

FIG. 2F is a block diagram illustrating additional detail of a solder ball attach process described with reference to FIG. 2A, according to an embodiment;

FIG. 2G is a block diagram illustrating additional detail of a testing process described with reference to FIG. 2A, according to an embodiment; and

FIG. 3 is a flow chart illustrating a method for assembling a semiconductor device, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements.

Similarly, the functionality of various mechanical elements, members, or components for forming modules, sub-assemblies and assemblies assembled in accordance with a structure for an apparatus may be implemented using various materials and coupling techniques, depending on the application requirements. Descriptive and directional terms used in the written description such as top, bottom, upper, lower, left, right, and similar others, refer to the drawings themselves as laid out on the paper and not to physical limitations of the disclosure unless specifically noted. The accompanying drawings may not to be drawn to scale and some features of embodiments shown and described herein may be simplified or exaggerated for illustrating the principles, features, and advantages of the disclosure.

It is well known that substrate suppliers typically provide substrates in the form of strip-like substrate sheets in which a plurality of substrates are formed consecutively to facilitate efficient handling in a subsequent process of manufacturing semiconductor devices. Defective substrates are identified by a mark, e.g., an X mark. The manufacturer may continue with the sequential processing of the strip-like substrate sheets, including defective ones, by performing value added assembly operations, thereby increasing material costs, increasing waste, and reducing manufacturing efficiency. This problem may be addressed by receiving and processing defect free singulated substrates for the semiconductor device assembly process.

According to one embodiment, in a method and system assembling a semiconductor device, a tray is configured to provide an array of bins arranged in m rows and n columns, where m and n are integers. The tray containing defect free singulated substrates is received from a substrate supplier for assembly. Each one of the defect free singulated substrates, which is disposed in a corresponding bin of the tray, is accessible in a concurrent or sequential manner, thereby enabling concurrent or sequential assembly of m*n ones of the defect free singulated substrate. The assembly process for the semiconductor device starting from the defect free singulated substrate includes die attach, wire bonding, mold press, laser marking, solder ball attach, and testing operations. Assembly of the defect free singulated substrates avoids material loss and increases manufacturing efficiency.

The following terminology may be useful in understanding the present disclosure. It is to be understood that the terminology described herein is for the purpose of description and should not be regarded as limiting.

Defect Free—A product or a service that is in compliance with mutually agreed upon quality standards between a provider and a receiver. For example, a buyer and a seller may agree that 1 defective unit per million units constitutes a defect free certification. Supplier may certify that a shipment of 1 million units of a product is defect free by submitting documentation, e.g., test results, stating that the number of defective units is less than or equal to 1.

Semiconductor Package (or Package)—A semiconductor package provides the physical and electrical interface to at least one integrated circuit (IC) or die included in a semiconductor device for connecting the IC to external circuits. The package protects the IC from damage, contamination, and stress that result from factors such as handling, heating, and cooling.

Semiconductor Device—A semiconductor device is an electronic component that utilizes electronic properties of semiconductor materials to perform a desired function. A semiconductor device may be manufactured as a single discrete device or as one or more ICs packaged into a module.

Configuration—Describes a set up of an element, a circuit, a package, an electronic device, and similar other, and refers to a process for setting, defining, or selecting particular properties, parameters, or attributes of the device prior to its use or operation. Some configuration attributes may be selected to have a default value. For example, a tray may include a plurality of compartments or bins arrange in a matrix. The matrix arrangement of bins may be configured to have 6 rows and 6 columns or 1 row and 8 columns by adjusting the dimensions of each bin.

Ball grid array (BGA)—A type of chip package type that enables direct mounting of the chip to a substrate or printed circuit board via solder balls or bumps, which are mounted on corresponding bond pads. The solder balls or bumps are arranged in a grid-style array and found on the underside of the chip to make the electrical connection to the outside.

Wirebond package—Wirebonding is an electrical interconnection technique that uses thin wires and a bonding agent such as a heat, pressure and ultrasound energy or a combination thereof. The thin wires are typically bonded on corresponding bond pads of a chip. Semiconductor device packages that use wirebonding (referred to as a ‘wirebond package’) include ball grid array (single chip and multi-chip), ceramic and plastic quad flat packages, chip scale packages, and a chip on board (COB) package.

Substrate—A substrate is an underlying material used to fabricate a semiconductor device. In addition to providing base support, substrates are also used to provide electrical interconnections between the IC chip and external circuits. Two categories of substrates that are used to fabricate the semiconductor device include rigid substrates and flexible tape substrates (may also be referred to as film substrates). Rigid substrates are typically composed of a stack of thin layers or laminates, and are often referred to as multilayer laminate substrates. In some applications, the laminate substrate may include a single layer of dielectric material and a single layer of metal. Flexible tape substrates are typically composed of polymer material such as polyimide, and are often referred to as a polyimide tape substrate. The polyimide tape substrate, which typically includes at least one metal layer, is generally cheaper, thinner and more flexible compared to the multilayer laminate substrate. Interconnecting patterns such as vias provide electrical coupling between the multiple layers of the substrate. The conductive layers typically include traces of a metal foil bonded to a polymer substrate.

Semiconductor Device Manufacturing—A process to manufacture semiconductor devices from silicon typically includes the following (highly simplified) production steps: production of raw silicon wafers, wafer fabrication to fabricate ICs, and assembly, packaging, and testing of individual ICs to manufacture a finished product, e.g., the semiconductor device. Assembling generally refers to the process of fitting together components or parts into a functional semiconductor device. Packaging generally refers to the steps performed to protect the IC from damage, contamination, and stress that result from factors such as handling, heating, and cooling. Packaging may be considered to be an integral part of the assembly process that makes the semiconductor device reliable, robust, and convenient to use. It is well known that each step in the fabrication process (including steps in the assembly process) may be performed by different manufacturers, which are often located in different countries.

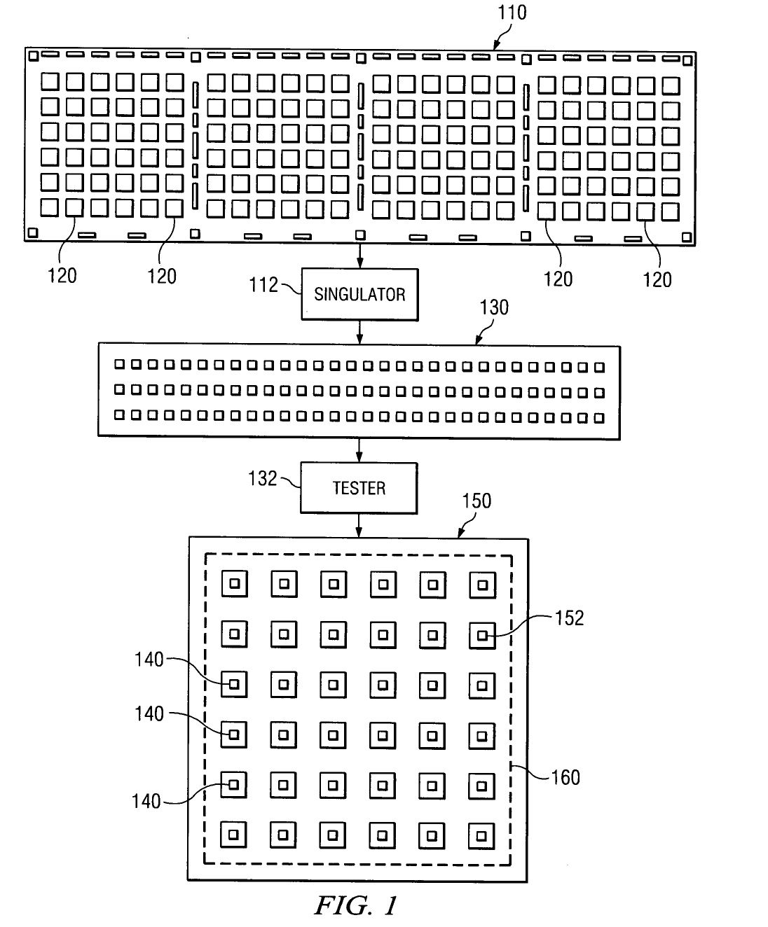

An apparatus and a method that is used for assembling a semiconductor device is described with reference to FIGS. 1, 2A, 2B, 2C, 2D, 2E, 2F, 2G and 3.

FIG. 1 illustrates a block diagram to fabricate defect free singulated substrates, according to an embodiment. A strip-like substrate sheet 110 includes a plurality of substrates 120 that are formed consecutively, e.g., in a 6×6 matrix arrangement. The size of the substrate sheet 110 and a number of the plurality of substrates 120 included in the substrate sheet 110 may vary with each application. As described earlier, the substrate sheet 110 includes multiple layers (not shown) made of alternating core material and conductive layers. The core material acts as a stiffener and insulator while the conductive layers are etched to form conductive traces for electrical interconnections.

The substrate sheet 110 is singulated, e.g., cut into single substrates, by a singulator 112 to form singulated substrates 130. The singulated substrates 130 are tested by a tester 132 to determine a pass or fail status. The singulated substrates 130 that have been determined to have a pass status are identified as defect free singulated substrates 140. The singulated substrates 130 that have been determined to have a fail status are identified as defective singulated substrates. The defect free singulated substrates 140 are correspondingly placed in a tray 150 having an array of bins 160 arranged in m rows and n columns, where m and n are positive integers. That is, each defect free simulated substrate 152 is disposed in a corresponding bin. In the depicted embodiment, m and n are equal and have a value of 6. It is understood that the value of integers m and n may vary for each application. The tray 150 advantageously functions as a container to house the defect free singulated substrates 140, provides ease of use to transport the defect free singulated substrates 140 from one location to another, provides protection to the defect free singulated substrates 140 from potential damage, and facilitates concurrent or sequential access for the assembly of m*n ones of the defect free singulated substrate 152. In a particular embodiment, the testing of the substrate sheet 110 may be performed before the singulation to identify defect free ones. As described herein, the process to assemble each one of the defect free singulated substrate 152 as a starting point to fabricate a finished semiconductor device is referred to as the one piece assembly process.

In an embodiment, the tray 150 may be fabricated from a variety of materials including plastic, metal, metal alloys, glass, composites, and similar others. In an embodiment, multiple trays having different properties such as materials used may be selected based on the process condition encountered during an assembly operation. For example, a lightweight and sturdy tray may be desirable for transportation and handling. During electrical testing, a tray that is fabricated from a conductive material capable of being grounded may be desirable. A heat resistant tray may be desirable during a curing or molding process. The materials used for the tray may be selected to provide a configurable level of heat protection, e.g., withstand heat up to 150 degrees Celsius, or withstand heat greater than or equal to 250 degrees Celsius. In an embodiment, the multiple trays may be configured to have an identical arrangement of the array of bins 160. In a particular embodiment, a single tray using particular composite materials or a single tray having a protective coating may be fabricated in accordance with desired specifications such as weight, strength, temperature profile, and similar others. The single tray may be used during all of the assembly operations.

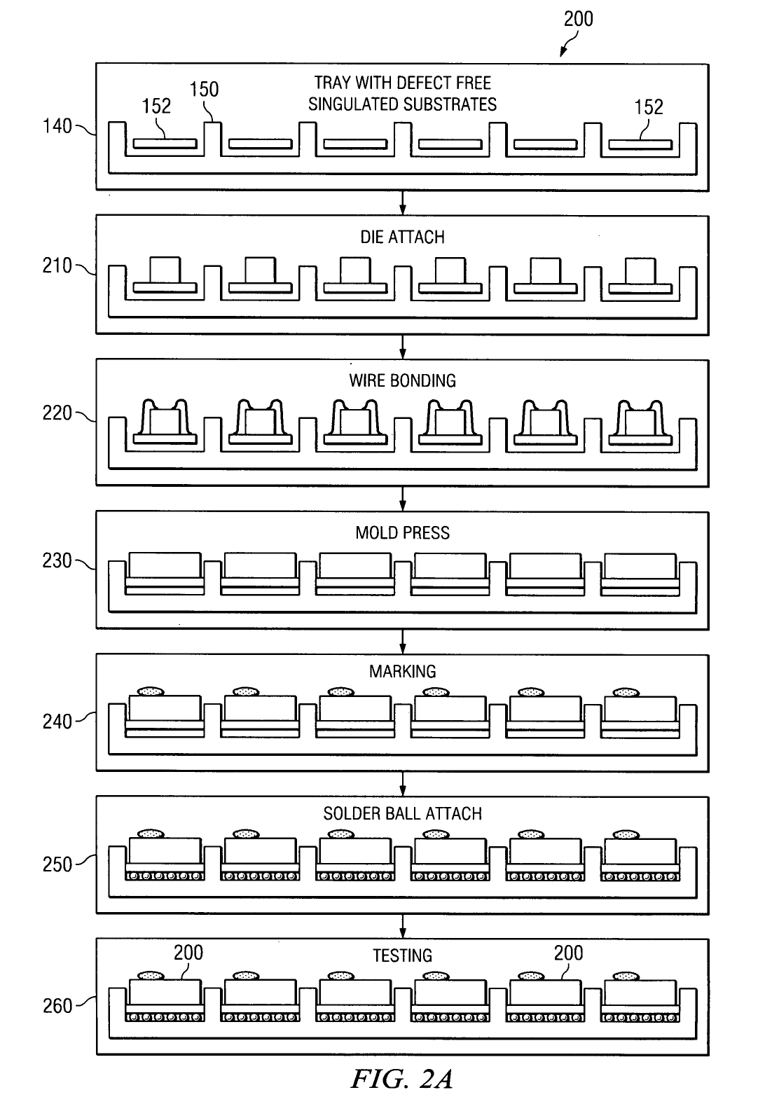

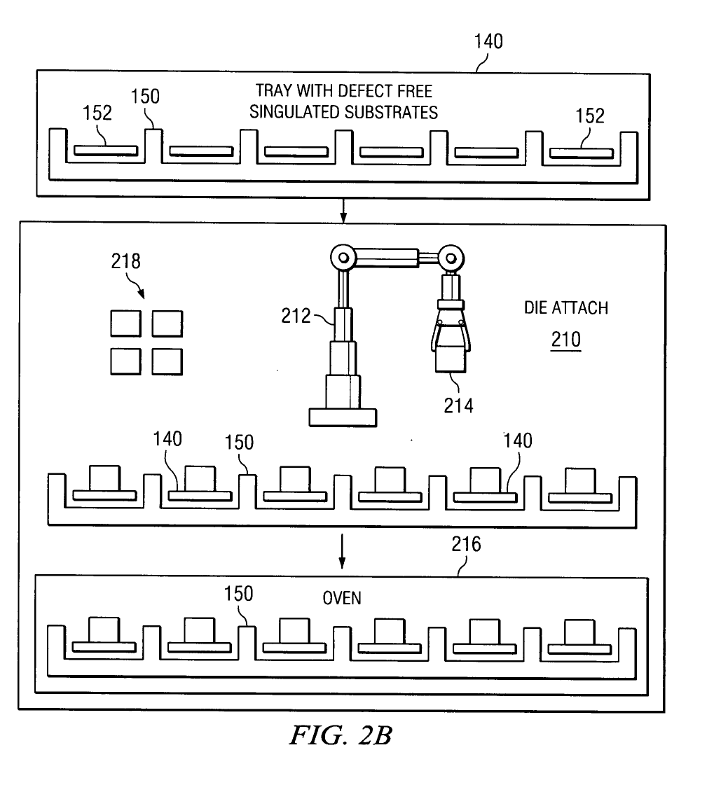

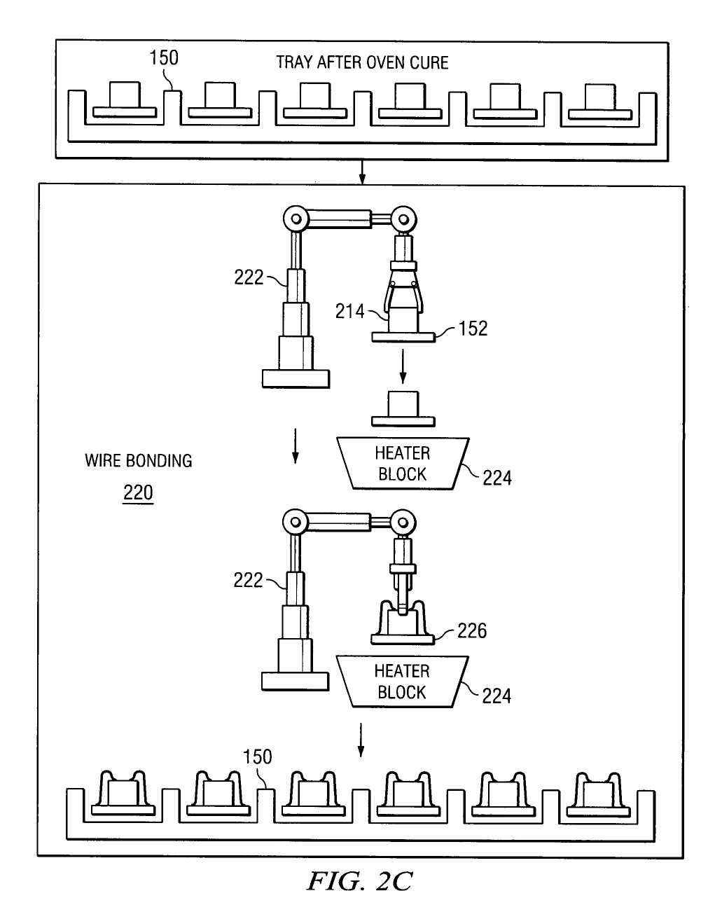

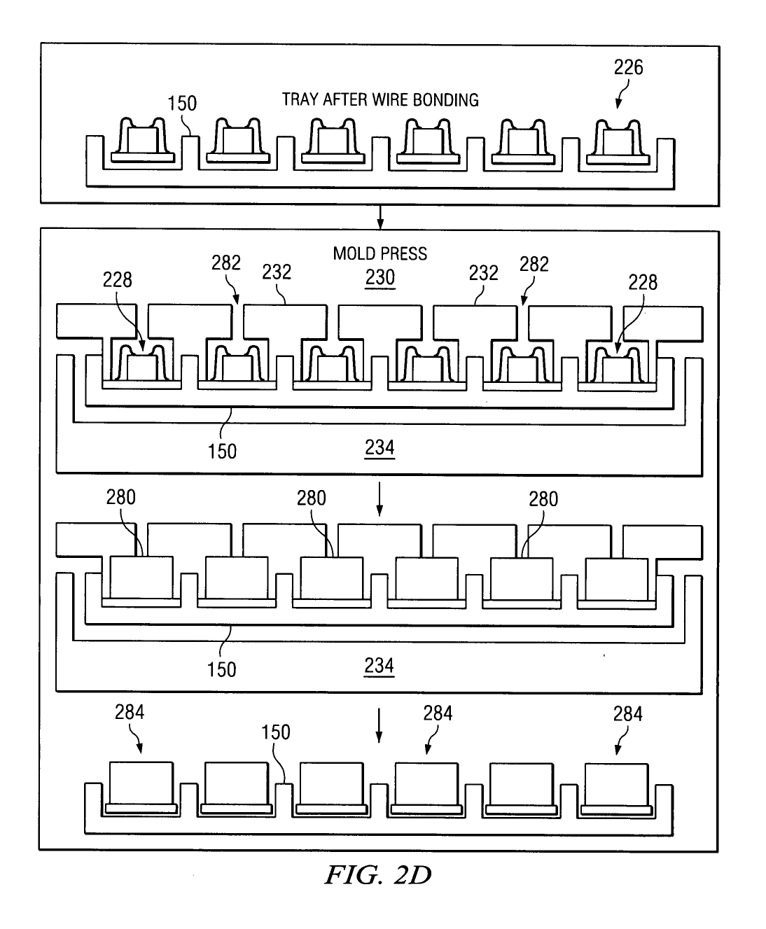

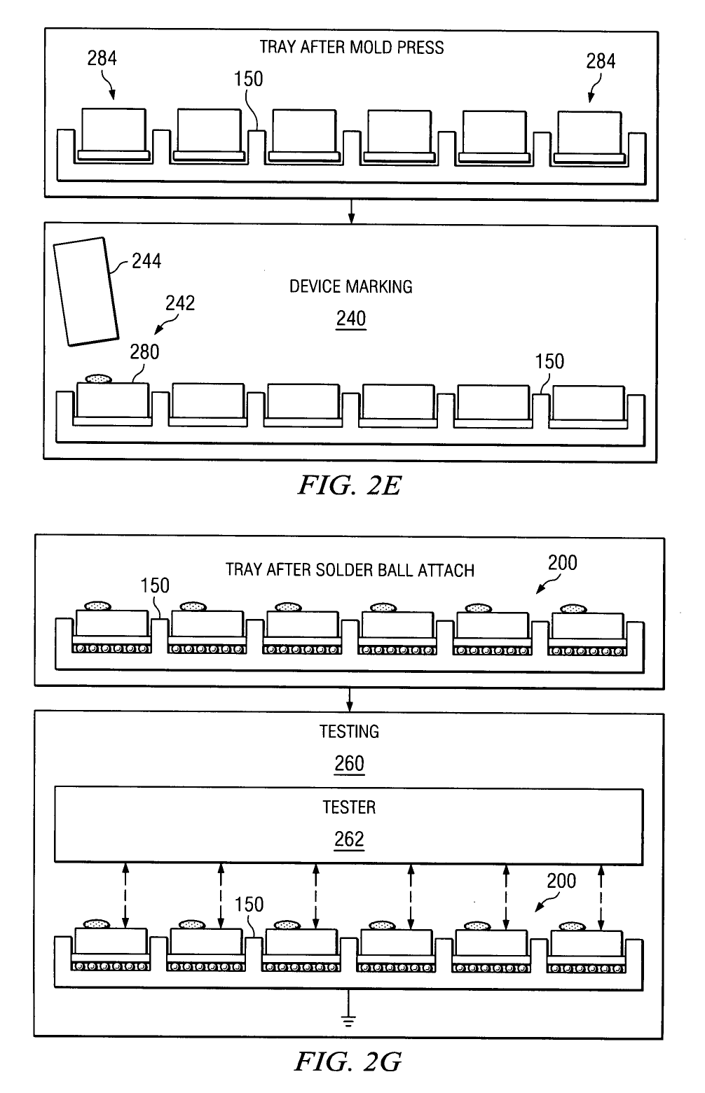

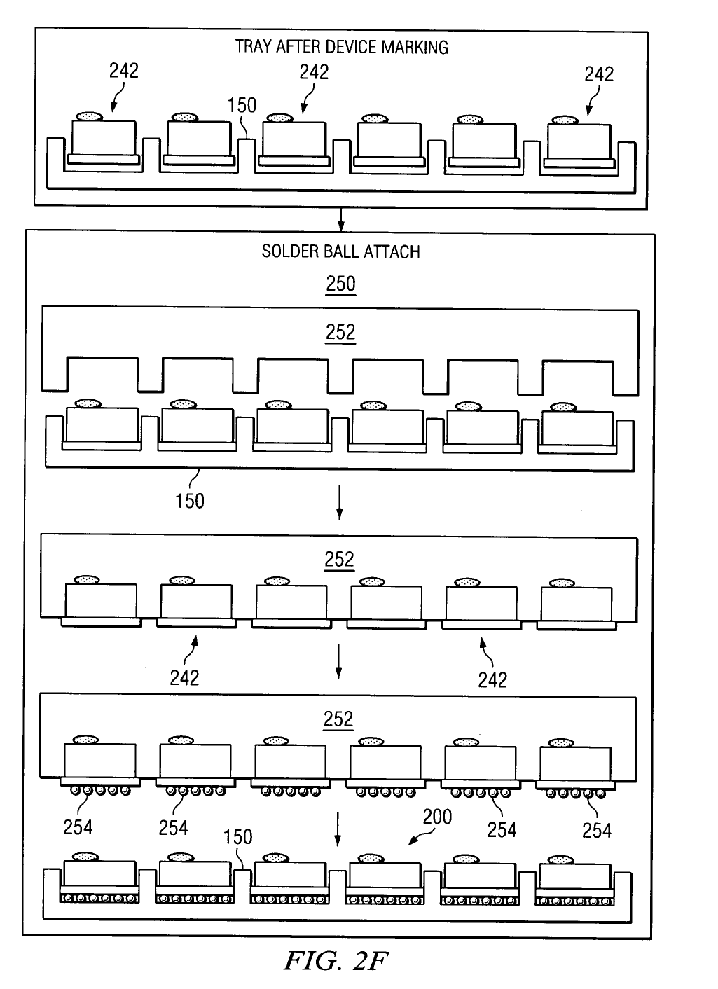

FIG. 2A illustrates a block diagram of a one piece assembly process 200 for the defect free singulated substrates 140 described with reference to FIG. 1, according to an embodiment. The tray 150 containing m*n ones of the defect free singulated substrates 140 is received for assembly processing, where m and n have a value of 6. Each defect free singulated substrate 152 undergoes value added operations in sequence to fabricate a semiconductor device 200. The value added operations performed in sequence include die attach 210, wire bonding 220, mold press 230, device marking 240, solder ball attach 250, and testing 260. Multiple ones of the defect free singulated substrate 152 may be processed concurrently or in parallel. That is, particular operations such as mold press 230 may be performed in parallel to concurrently mold multiple ones, e.g., n at one time or m at one time, of the defect free singulated substrate 152. Additional detail of the value added operations are described with reference to FIGS. 2B, 2C, 2D, 2E, 2F and 2G.

FIG. 2B is a block diagram illustrating additional detail of the die attach 210 described with reference to FIG. 2A, according to an embodiment. A sectional view of the tray 150 is shown to include 6 defect free singulated substrates disposed in 6 corresponding bins, the value of m or n being equal to 6. The die attach 210 process includes a pick-and-place machine 212 operable to pick up a die 214 from a plurality of singulated dies 218 of a silicon wafer and place the die 214 on a selectable one of the defect free singulated substrates 140. A die attach compound (not shown) is disposed between the die 214 and the selected one of the defect free singulated substrates 140. In an exemplary, non-depicted embodiment, the pick-and-place machine 212 may be operable to pick multiple dies, e.g., 6 dies, and place them concurrently on a corresponding one of the defect free singulated substrates 140. Once a die is attached to each one of the defect free singulated substrates 140, the tray 150 is placed in an oven 216 to cure the die attach compound.

FIG. 2C is a block diagram illustrating additional detail of the wire bonding 220 described with reference to FIG. 2A, according to an embodiment. A sectional view of the tray 150 is shown after the oven cure. The tray 150 includes 6 dies attached to 6 corresponding defect free singulated substrates disposed in 6 corresponding bins, the value of m or n being equal to 6. The wire bonding 220 process includes a pick-and-place machine 222 operable to pick up the die 214 attached to the singulated substrate 152 and place the die 214 attached to the singulated substrate 152 on a heater block 224. The heater block 224 is operable to heat the die 214 attached to the singulated substrate 152 to a desired temperature profile, e.g., heat up to approximately 160 degrees Celsius. A wire bonding machine (not shown) is operable to form wire bonds between the die 214 and the singulated substrate 154, thereby forming a wire bonded die 226. The wire bonded die 226 is picked by the pick-and-place machine 222 and placed back into a corresponding bin of the tray 150. In an exemplary, non-depicted embodiment, the wire bonding operation may be performed concurrently on multiple ones of the defect free singulated substrates 140 using multiple heater blocks.

FIG. 2D is a block diagram illustrating additional detail of the mold press 230 described with reference to FIG. 2A, according to an embodiment. A sectional view of the tray 150 is shown after the wire bonding 220. The tray 150 is disposed between an upper mold die 232 and a lower mold die 234. A cavity 228 is formed between the upper mold die 232 and the wire bonded die 226 corresponding to each bin. The cavity 228 is filled by a mold compound (not shown) to form a mold 280 around the wire bonded die 226. A mold press machine (not shown) is operable to inject the molding compound into the cavity 228 via an opening 282. In an exemplary, non-depicted embodiment, the mold press operation may be performed concurrently on multiple ones of the wire bonded die 226 using the mold press machine. The mold 280 is cured to form a molded semiconductor device 284. After the curing, the upper mold die 232 and the lower mold die 234 are removed to expose the tray 150, which houses multiple ones of the molded semiconductor device 284.

FIG. 2E is a block diagram illustrating additional detail of the device marking 240 described with reference to FIG. 2A, according to an embodiment. A sectional view of the tray 150 is shown after forming the molded semiconductor device 284. A marking device 244 such as a laser marker is operable to inscribe on an upper surface of the mold 280 of the molded semiconductor device 284 to form a marked semiconductor device 242. The inscription may include information to identify the product such as model number, name, and similar other. In an exemplary, non-depicted embodiment, the device marking 240 may be performed concurrently on multiple ones of the molded semiconductor device 284 using multiple markers.

FIG. 2F is a block diagram illustrating additional detail of the solder ball attach 250 described with reference to FIG. 2A, according to an embodiment. A sectional view of the tray 150 is shown after the device marking 240. Using a vacuum, a chucking tool 252 is operable to pick multiple ones of the marked semiconductor device 242, e.g., n ones, where n is equal to 6, thereby exposing a bottom surface of the marked semiconductor device 242. A solder ball attaching machine (not shown) is operable to attach solder balls 254 as a BGA on the bottom surface to form the semiconductor device 200. The chucking tool 252 is operable to place multiple ones of the semiconductor device 200 in corresponding bins of the tray 150.

FIG. 2G is a block diagram illustrating additional detail of the testing 260 described with reference to FIG. 2A, according to an embodiment. A sectional view of the tray 150 is shown after the solder ball attach 250. In a particular embodiment, the tray 150 is fabricated from a conductive material, the tray 150 capable of being coupled to a ground reference to avoid electrostatic damage to the semiconductor device 200. A tester 262 is operable to test each one of the semiconductor device 200 to determine a pass or fail status. In an exemplary, non-depicted embodiment, the tester 262 may be operable to concurrently test multiple ones of the semiconductor device 200. In an exemplary, non-depicted embodiment, the semiconductor device 200 is at least one of a microprocessor, an application specific integrated circuit (ASIC), a digital signal processor, a radio frequency chip, a memory, a microcontroller, and a system-on-a-chip, or a combination thereof. As described earlier, although a single tray is shown to be used during the assembly process, it is understood that multiple trays having the same bin arrangement may be used to match the desired tray characteristics during each assembly operation.

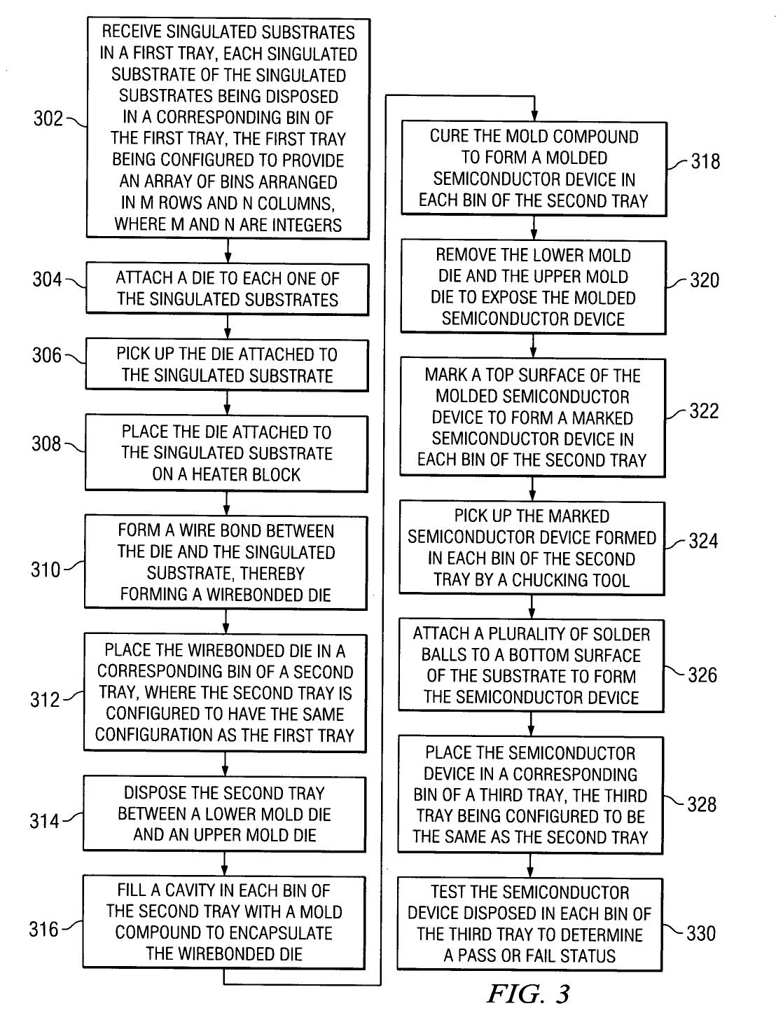

FIG. 3 is a flow chart illustrating a method for assembling a semiconductor device, according to an embodiment. In a particular embodiment, the method is used to assemble the semiconductor device 200 described with reference to FIGS. 2A, 2B, 2C, 2D, 2E, 2F, and 2G. At step 302, singulated substrates are received. Each singulated substrate of the singulated substrates is disposed in a corresponding bin of a first tray, the first tray being configured to provide an array of bins arranged in m rows and n columns, where m and n are integers. In an embodiment, the singulated substrates are certified to have a defect free status prior to the receiving, the defect free status being indicative of a compliance with acceptable quality standards. At step 304, a die is attached to each one of the singulated substrates. At step 306, the die attached to the singulated substrate is picked up, e.g., by a pick-and-place machine. At step 308, the die attached to the singulated substrate is placed on a heater block. At step 310, a wire bond is formed between the die and the singulated substrate, thereby forming a wirebonded die.

At step 312, the wirebonded die is placed in a corresponding bin of a second tray, where the second tray is configured to have the same configuration as the first tray, e.g., both include m*n bins arranged in m rows and n columns. At step 314, the second tray is disposed between a lower mold die and an upper mold die. At step 316, a cavity in each bin of the second tray is filled with a mold compound, the mold compound encapsulating each one of the wirebonded die. At step 318, the mold compound is cured to form a molded semiconductor device in each bin of the second tray. At step 320, the lower mold die and the upper mold die are removed to expose the molded semiconductor device formed in each bin of the second tray. At step 322, a top surface of the molded semiconductor device is marked to form a marked semiconductor device in each bin of the second tray.

At step 324, the marked semiconductor device formed in each bin of the second tray is picked up by a chucking tool. At step 326, a plurality of solder balls are attached to a bottom surface of the substrate to form the semiconductor device. At step 328, the semiconductor device is placed in a corresponding bin of a third tray, the third tray being configured to be the same as the second tray. At step 330, the semiconductor device disposed in each bin of the third tray is tested to determine a pass or fail status.

Various steps described above may be added, omitted, combined, altered, or performed in different orders. For example, a step of testing may be performed after each assembly operation such as die attach, wire bonding, mold press, and similar other.

Several advantages are achieved by the method and system according to the illustrative embodiments presented herein. The embodiments advantageously provide for assembling semiconductor devices by receiving defect free components for the assembly. By using defect free components as a starting point for the assembly, there are assured savings in material costs since no material is wasted on assembling defective semiconductor devices. The defect free singulated substrates used as the base for the semiconductor device assembly are advantageously identified as being in full compliance with acceptable quality standards (referred to as ‘defect free’). Each defect free singulated substrate is disposed in a corresponding bin of a tray, the bins being arranged in a matrix layout that advantageously provide access to tools for performing value added sequential or parallel processing operations on the defect free singulated substrate. Assembly operations including die attach, wire bonding, mold press, laser marking, solder ball attach, and testing may be advantageously performed in sequence or in parallel to efficiently fabricate the semiconductor device.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of using a one piece singulated substrate as a starting component for assembling a semiconductor device, those of ordinary skill in the art will appreciate that the processes disclosed herein are capable of assembling components other than substrates.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for assembling a semiconductor device, the method comprising:
receiving singulated substrates, wherein each singulated substrate of the singulated substrates is disposed in a corresponding bin of a first tray, the first tray being configured to provide an array of bins arranged in m rows and n columns, wherein m and n are integers; and
attaching a die to each one of the singulated substrates.

2. The method of claim 1 further comprising:
picking the die attached to the singulated substrate;
placing the die attached to the singulated substrate on a heater block; and
forming a wire bond between the die and the singulated substrate to form a wirebonded die.

3. The method of claim 2 further comprising:
placing the wirebonded die in a corresponding bin of a second tray, wherein the second tray is configured to be equal to the configuration of the first tray;
disposing the second tray between a lower mold die and an upper mold die, the second tray including m*n ones of the wirebonded die;
filling a cavity in each bin of the second tray with a mold compound, the mold compound encapsulating the m*n ones of the wirebonded die;
curing the mold compound to form a molded semiconductor device in each bin of the second tray;
removing the lower mold die and the upper mold die to expose the molded semiconductor device formed in each bin of the second tray; and
marking a top surface of the molded semiconductor device to form a marked semiconductor device in each bin of the second tray.

4. The method of claim 3 further comprising:
picking the marked semiconductor device formed in each bin of the second tray by a chucking tool;
attaching a plurality of solder balls to a bottom surface of the substrate to form the semiconductor device;
placing the semiconductor device in a corresponding bin of a third tray, wherein the third tray is configured to be equal to the configuration of the second tray; and
testing the semiconductor device disposed in each bin of the third tray.

5. The method of claim 4, wherein the picking, the attaching, the placing, and the testing of the semiconductor device is performed in a concurrent manner, thereby enabling concurrent assembly of m*n ones of the semiconductor device.

6. The method of claim 4, wherein the first tray, the second tray, and the third tray are the same tray.

7. The method of claim 4, wherein the first tray is fabricated from a heat resistant material, wherein the second tray is fabricated from a metal, wherein the third tray is fabricated from a conductive material, the third tray capable of being electrically coupled to a ground reference.

8. The method of claim 1, wherein the singulated substrates are certified to have a defect free status prior to the receiving, wherein the defect free status is indicative of a compliance with mutually agreed upon quality standards between a receiver and a sender.

9. The method of claim 8, wherein the sender is a substrate supplier providing the singulated substrates, the substrate supplier certifying the defect free status in response to testing the singulated substrates.

10. The method of claim 1, wherein the singulated substrates disposed in the array of bins of the tray are accessible in a concurrent manner, thereby enabling concurrent assembly of m*n ones of the die attached to the singulated substrate.

11. The method of claim 1, wherein the singulated substrates disposed in the array of bins of the tray are accessible in a sequence, thereby enabling sequential assembly of m*n ones of the die attached to the singulated substrate.

12. The method of claim 1, wherein the semiconductor device is at least one of a microprocessor, an application specific integrated circuit (ASIC), a digital signal processor, a radio frequency chip, a memory, a microcontroller, and a system-on-a-chip, or a combination thereof.

13. A method for assembling a semiconductor device, the method comprising:
singulating a substrate sheet to provide singulated substrates, the substrate sheet configured to include an array of substrates arranged in m rows and n columns, wherein m and n are integers;
testing the singulated substrates to identify defect free singulated substrates;
placing one of the defect free singulated substrates into a corresponding bin of a tray, the tray being configured to include an array of bins that match the array of substrates; and
sending the tray containing the defect free singulated substrates for the assembling of the semiconductor device.

14. The method of claim 13, wherein the defect free singulated substrates are provided by a first manufacturer, wherein the assembling of the semiconductor device is partially performed by the first manufacturer and a second manufacturer that is different than the first manufacturer.

15. The method of claim 13, wherein the tray is fabricated from a heat resistant material.

16. The method of claim 13, wherein a percentage ratio of the defect free singulated substrates to the singulated substrates is between 80% and 90%.

17. The method of claim 13, wherein the semiconductor device is at least one of a microprocessor, an application specific integrated circuit (ASIC), a digital signal processor, a radio frequency chip, a memory, a microcontroller, and a system-on-a-chip, or a combination thereof.

18. The method of claim 13, wherein the defect free singulated substrates disposed in the array of bins of the tray are accessible in a concurrent manner, thereby enabling concurrent assembly of m*n ones of the defect free singulated substrates.

19. An apparatus for packaging substrates, the apparatus comprising:
defect free singulated substrates, wherein a substrate sheet is singulated to generate singulated substrates, wherein the singulated substrates are tested to generate the defect free singulated substrates; and
a tray configured to include an array of bins arranged in m rows and n columns, wherein m and n are integers, wherein each one of the defect free singulated substrates is disposed in a corresponding bin.

20. The apparatus of claim 19, wherein the tray is fabricated from a heat resistant material.
